(19) United States
(12) Patent Application Publication
(10) Pub. No.: US 2008/0233301 A1
(43) Pub. Date: Sep. 25, 2008

(54) STACKED-FILM-FORMING SYSTEM, SPUTTERING APPARATUS, AND METHOD FOR FORMING STACKED FILM

(75) Inventors: Katsunori Takahashi, Higashine (JP); Yoichi Sato, Higashine (JP); Kazuya Takahashi, Higashine (JP)

Correspondence Address: GREER, BURNS & CRAIN, 300 S WACKER DR, 25TH FLOOR, CHICAGO, IL, 60606, US

(73) Assignee: FUJITSU LIMITED, Kawasaki-shi (JP)

(21) Appl. No.: 12/041,254

(22) Filed: Mar. 3, 2008

(30) Foreign Application Priority Data
Mar. 19, 2007 (JP) 2007-069900

(51) Int. Cl. B05D 1/36; B05C 13/00; C23C 16/00; C23C 14/00

(52) U.S. Cl. 427/402; 118/500; 118/728; 204/298.01

(57) ABSTRACT

According to an aspect of an embodiment, a stacked-film-forming system for forming a stacked film has a first film-forming apparatus including a holder having a frame surrounding the substrate and a holding mechanism for holding the substrate inside the frame so that the major surface of the substrate is vertically oriented, a material emission portion for emitting a material of a first film toward the substrate held in the holder, and a shield being disposed between the holder and the material emission portion and shielding areas except for a portion of the frame from the emitted material. The portion is located at the upper part of the substrate. The stacked-film-forming system has a second film-forming apparatus for forming a second film, on the first film. The second film is made of a material different from the material of the first film.

### BACKGROUND OF THE INVENTION

This art relates to a stacked-film-forming system for forming a stacked film by stacking a plurality of films made of different materials on a substrate, a sputtering apparatus for forming a film by a sputtering method on a substrate, and a method for forming a stacked film by stacking a plurality of films made of different materials on a substrate.

Examples of arts related to the stacked-film-forming system, the sputtering apparatus and the method forming the film are disclosed in Japanese Laid-open Patent Publication Nos. 10-204616 and 2001-148118.

### SUMMARY

According to an aspect of an embodiment, a stacked-film-forming system for forming a stacked film comprises: a first film-forming apparatus including a holder having a frame surrounding the substrate and a holding mechanism for holding the substrate inside the frame so that the major surface of the substrate is vertically oriented, a material emission portion for emitting a material of a first film toward the substrate held in the holder, and a shield being disposed between the holder and the material emission portion and shielding areas except for a portion of the frame from the emitted material, the portion being located at the upper part of the substrate, and a second film-forming apparatus for forming, on the first film, a second film made of a material different from the material of the first film.

### BRIEF DESCRIPTION OF THE DRAWINGS

FIG. 1 is a view showing an embodiment of the present invention;

FIG. 2 is a flowchart showing a flow of a process of forming a stacked film performed by a stacked-film-forming system 10 shown in FIG. 1;

FIGS. 3A and 3B are views showing the detailed structure of a substrate holder 220;

FIGS. 4A and 4B are views showing the detailed structure of a shield 240; and

FIGS. 5A and 5B are views of a shielding portion 241 and correspond to FIGS. 4A and 4B, respectively.

### DESCRIPTION OF THE PREFERRED EMBODIMENTS

An example of popular magnetic recording media is a magnetic disk used in a magnetic disk device. In most magnetic recording media, a stacked film including a magnetic recording media, a stacked film including a magnetic film and a carbon protective film is provided on a substrate made of a nonmagnetic material. Each of these films is generally formed by a sputtering method in which a film is formed by depositing a material of a film on a substrate by sputtering the material from a target containing the material to the substrate. In this method, the material used for forming a film may also be inadvertently deposited inside a sputtering apparatus for forming a film by a sputtering method. As a result, an unnecessary film may be formed on areas other than the substrate. In particular, carbon deposited inside the sputtering apparatus may become detached. Consequently, the carbon may interfere with formation of a magnetic film, or damage the formed magnetic film, and thus a problem such as degradation of the quality of the magnetic recording medium may occur. In order to prevent such a problem from occurring, it is necessary to carefully remove carbon deposited inside the sputtering apparatus each time a carbon protective film is formed. Accordingly, the operational efficiency is markedly decreased.

Therefore, in many known sputtering apparatuses for forming a carbon protective film, portions inside the apparatus on which carbon is likely to be deposited are made of aluminum or a stainless steel, which has relatively good adhesion with carbon. This structure can suppress detachment of carbon in the apparatus. Accordingly, the number of times the deposited carbon is removed can be decreased by accepting deposition of carbon to some extent. Thus, the operational efficiency can be improved.

In addition, in order to further suppress the detachment of carbon inside a sputtering apparatus and to achieve an effect of further decreasing the number of times the deposited carbon is removed, a technique has been proposed in which a zinc plating film, which has good adhesion with carbon, is formed in advance on the surfaces of portions inside the sputtering apparatus on which carbon is likely to be deposited.

A substrate to be processed in a sputtering apparatus is generally placed in the apparatus in a state in which the substrate is held in a predetermined holder or the like. When carbon is deposited on and then detached from a component disposed near the substrate (hereinafter referred to as “near-substrate component”), such as the above-mentioned holder, the probability of the carbon falling on the substrate is high. Hitherto, such a near-substrate component is generally protected from a carbon flow during sputtering using a predetermined shield or the like so as to prevent carbon from being deposited thereon in the first place.

Recently, further increase in the recording density of magnetic recording media has been desired. To achieve this, the thickness of the carbon protective film in magnetic recording media has been significantly reduced. Consequently, the method of forming such a carbon protective film has been changed from a conventional sputtering method to a chemical vapor deposition (CVD) method, by which a thinner film can be formed. As a result, a stacked film used in magnetic recording media has been formed by a stacked-film-forming system including a sputtering apparatus with which a magnetic film is formed by a sputtering method and a CVD apparatus with which a carbon protective film is formed by a CVD method.

In the CVD method, a substrate is exposed to a compound gas containing a material of a film to be formed, and the material contained in the compound gas is deposited on the substrate by a chemical reaction. In CVD apparatuses used in the CVD method, deposition and detachment of carbon on and from areas other than the substrate can also cause problems, as in the case of the sputtering apparatuses described above. In the CVD method, carbon is inevitably deposited everywhere the compound gas reaches. Accordingly, unlike in the sputtering apparatuses, it may be impossible to prevent carbon from being deposited on a near-substrate component such as a holder. Therefore, in CVD apparatuses, it is believed that such deposition of carbon on a near-substrate component is inevitable. Accordingly, for example, detachment of deposited carbon is suppressed by forming a zinc plating film on a near-substrate component.

The formation of a carbon protective film using a CVD apparatus is performed after the formation of a magnetic film using a sputtering apparatus. A holder for holding a substrate is often repeatedly used in both apparatuses from the standpoint that, for example, labor, such as moving the substrate to another holder, can be saved. More specifically, when the formation of a magnetic film with a sputtering apparatus is finished, a substrate is transferred to a CVD apparatus in a state in which the substrate is held in a holder. Therefore, for example, in order to achieve good adhesion of carbon with a holder having, for example, a zinc plating film thereon in the CVD apparatus, the surface of the holder should be free of magnetic material, and thus, in the previous step of sputtering, the holder is protected in the sputtering apparatus by shielding the holder from a flow of magnetic material during sputtering deposition using a shield.

However, under the present situation, when a holder for holding a substrate is used in both a sputtering apparatus and a CVD apparatus, carbon deposited in the CVD apparatus is still frequently detached from the holder during repeated use. Accordingly, it is necessary to frequently perform cleaning of the holder or the like.

A description has been made of a problem of detachment of carbon from a holder for holding a substrate when the holder is repeatedly used in both a sputtering apparatus and a CVD apparatus, using an example of a stacked-film-forming system in which a magnetic film is formed with the sputtering apparatus and a carbon protective film is then formed with the CVD apparatus. However, such a problem also occurs in a stacked-film-forming system for forming a stacked film by stacking a plurality of films made of different materials on a substrate.

An embodiment of the present invention will now be described with reference to the drawings.

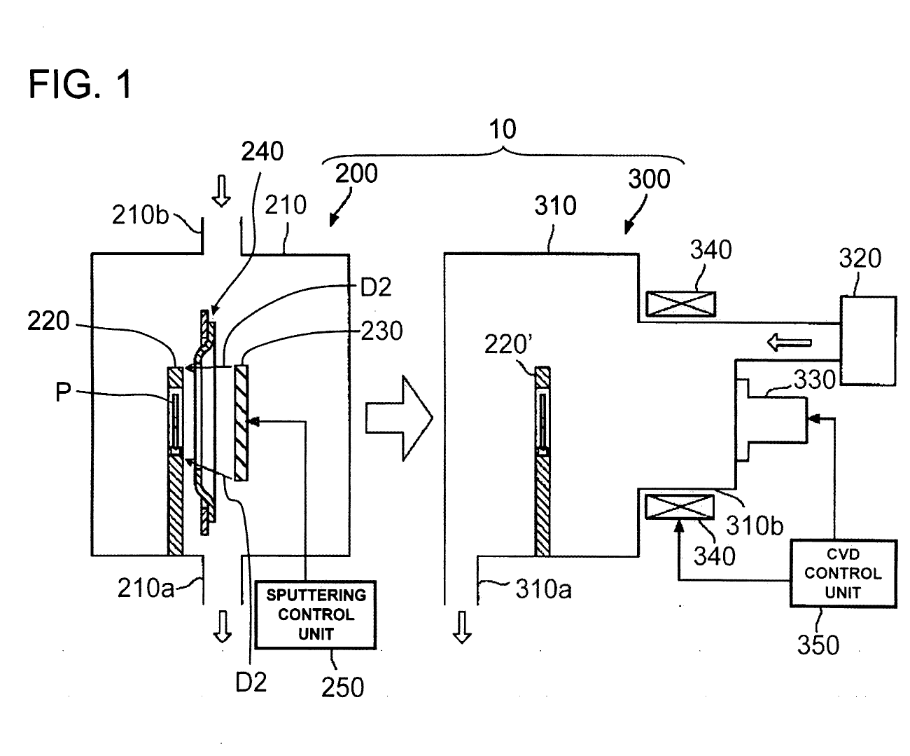

FIG. 1 is a view showing an embodiment of the present invention.

FIG. 1 shows a stacked-film-forming system 10 for forming a stacked film of a magnetic recording medium on the surface of a disc-shaped substrate P made of a nonmagnetic material. The stacked film includes a magnetic film and a carbon protective film for protecting the magnetic film. This stacked-film-forming system 10 forms the magnetic film by a sputtering method and forms the carbon protective film by a CVD method. The stacked-film-forming system 10 includes a sputtering apparatus 200 for forming a film by a sputtering method and a CVD apparatus 300 for forming a film by a CVD method. Herein, the stacked-film-forming system 10 corresponds to a stacked-film-forming system according to an embodiment of the present invention, and the sputtering apparatus 200 corresponds to a sputtering apparatus according to an embodiment of the present invention. The sputtering apparatus 200 also corresponds to an example of a first film-forming apparatus in the present invention, and the CVD apparatus 300 corresponds to an example of a second film-forming apparatus in the present invention. Furthermore, the magnetic film formed with the sputtering apparatus 200 corresponds to an example of a first film in the present invention, and the carbon protective film formed with the CVD apparatus 300 corresponds to an example of a second film in the present invention.

The sputtering apparatus 200 includes a sputtering chamber 210, a substrate holder 220, a magnetic material target 230, a shield 240, and a sputtering control unit 250. The substrate holder 220 corresponds to an example of a holder in the present invention, and the shield 240 corresponds to an example of a shielding portion in the present invention. The combination of the magnetic material target 230 and the sputtering control unit 250 corresponds to an example of a material emission portion in the present invention.

The CVD apparatus 300 includes a CVD chamber 310, a gas supply unit 320, a microwave source 330, a solenoid coil 340, and a CVD control unit 350.

Each of the components of the sputtering apparatus 200 and the CVD apparatus 300 will now be described on the basis of a flow of a process of forming a stacked film performed in the stacked-film-forming system 10.

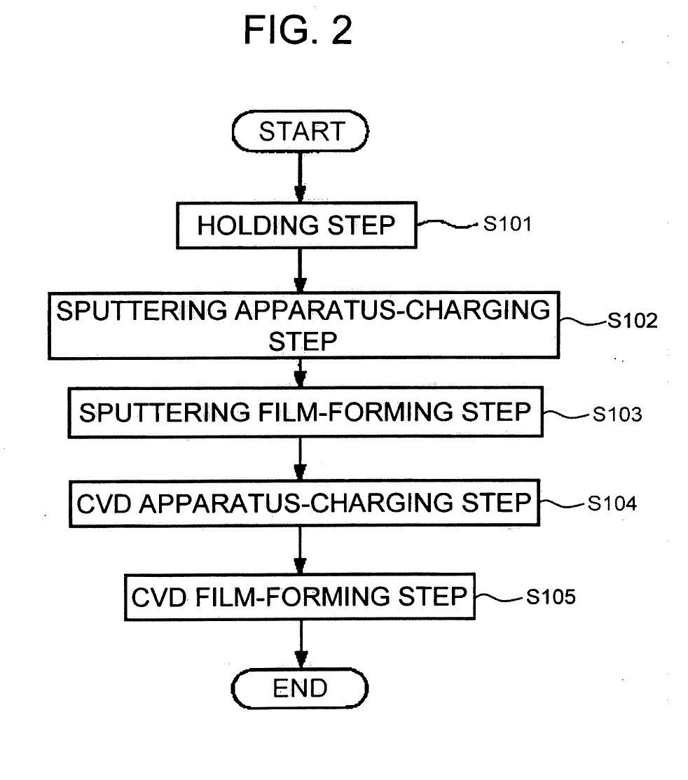

FIG. 2 is a flowchart showing a flow of a process of forming a stacked film performed in the stacked-film-forming system 10 shown in FIG. 1.

The process shown in the flowchart of FIG. 2 corresponds to a method for forming a stacked film according to an embodiment of the present invention.

A description will now be made basically with reference to the flowchart of FIG. 2, and as needed, with reference to FIG. 1 and other figures. In the following description, components shown in FIG. 1 may be referred to without particularly using reference numerals.

In the process shown in this flowchart, first, a holding step (Step S101) of holding a substrate P to be processed in a substrate holder 220 for holding a disc-shaped substrate is performed. This holding step (Step S101) corresponds to an example of a holding step in the present invention.

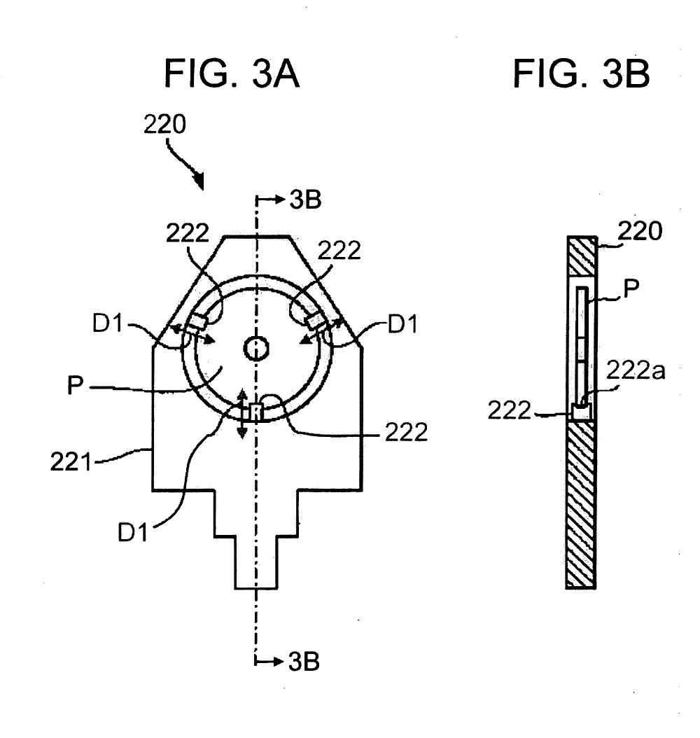

FIGS. 3A and 3B are views showing the detailed structure of the substrate holder 220.

FIG. 3A is a front view of the substrate holder 220. FIG. 3B is a cross-sectional view taken along line 3B-3B of FIG. 3A.

The substrate holder 220 includes a frame 221 and three holding mechanisms 222. The frame 221 includes a circular hole surrounding the disc-shaped substrate P. The holding mechanisms 222 hold the substrate P inside the hole of the frame 221 by a three-point support. As shown in FIG. 3B, a groove 222a is provided on the end of each of the holding mechanisms 222. The edge of the substrate P is fitted in the groove 222a of each holding mechanism 222, and the substrate P is held in the substrate holder 220. The holding mechanisms 222 can move in the directions shown by the corresponding arrows D1 in FIG. 3A, and the substrate P can be freely held in or detached from the holding mechanisms 222. The sputtering apparatus 200 in this embodiment is designed so that a magnetic film can be formed on substrates having various sizes. Therefore, the size of the hole provided in the frame 221 of the substrate holder 220 is somewhat larger than the designed maximum size of a substrate. In order to have a substrate held in the substrate holder 220, the amount of movement of the holding mechanisms 222 in the directions of the corresponding arrows D1 is adjusted in accordance with the size of the substrate.

After the holding of the substrate P in the substrate holder 220 is complete as described above, a sputtering apparatus-charging step (Step S102) of placing the substrate holder 220 holding the substrate P therein, the magnetic material target 230, and the shield 240 in the sputtering chamber 210 is performed, as shown in the flowchart of FIG. 2.

An outlet 210a and a gas inlet 210b are provided in the sputtering chamber 210. In a sputtering film-forming step (Step S103) described below, evacuation is performed from the outlet 210a and argon gas is then introduced from the gas inlet 210b, and thus the sputtering chamber 210 is filled with argon gas.

In the sputtering apparatus-charging step (Step S102), the substrate holder 220 holding the substrate therein is vertically placed in the sputtering chamber 210 so that an upper area of the substrate holder 220 described below is disposed at the upper side. A major surface of the substrate is vertically oriented.

The magnetic material target 230 contains a magnetic material used as the material of a magnetic film. In the sputtering apparatus-charging step (Step S102), the magnetic material target 230 is placed so that the surface of the substrate P held in the substrate holder 220 that is vertically disposed faces the surface of the magnetic material target 230.

The shield 240 controls a flow of the magnetic material sputtered from the magnetic material target 230 shown by the arrows D2 in FIG. 1 so that the magnetic material is not deposited in areas other than an area described below including the surface of the substrate P in the sputtering chamber 210. In the sputtering apparatus-charging step (Step S102), the shield 240 is placed between the magnetic material target 230 and the substrate holder 220 holding the substrate therein.

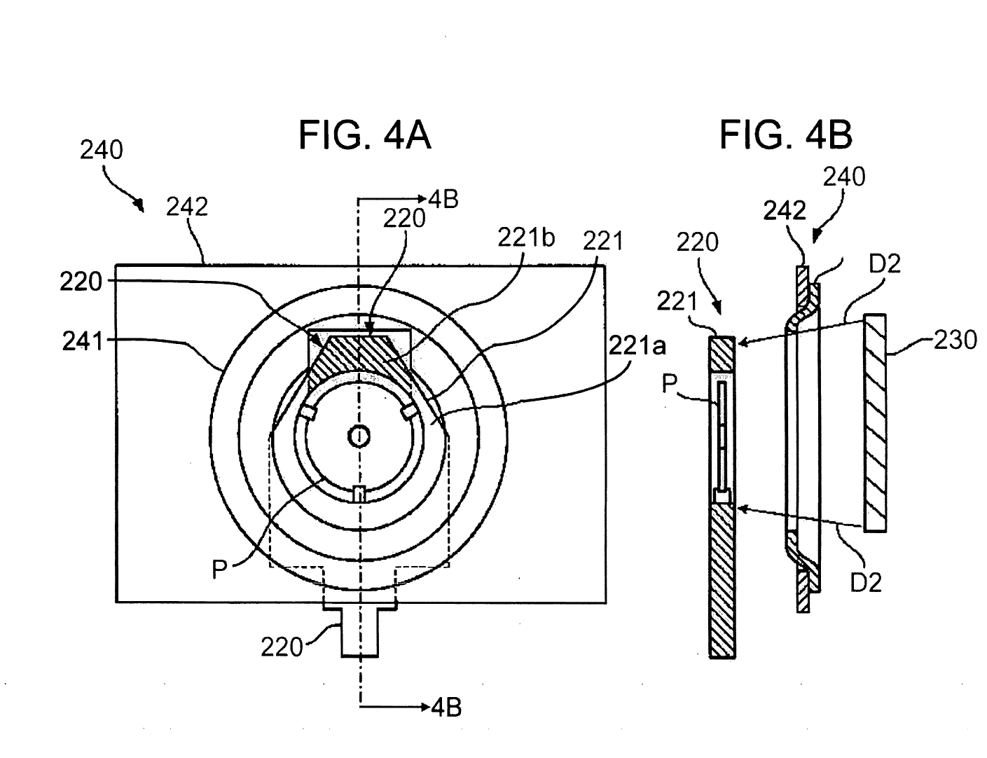

FIGS. 4A and 4B are views showing the detailed structure of the shield 240.

FIG. 4A shows a front view of the shield 240 together with the substrate holder 220 holding the substrate therein. FIG. 4B shows a cross-sectional view taken along line 4B-4B of FIG. 4A together with the substrate holder 220 holding the substrate therein and the magnetic material target 230.

The shield 240 includes a d shielding portion 241 having a shallow bowl shape a plate-shaped holding portion 242. The shielding portion 241 includes a hole through which the magnetic material sputtered from the magnetic material target 230 passes. The shielding portion 241 is fitted in the holding portion 242, and thus the holding portion 242 holds the shielding portion 241 so that the shielding portion 241 can be attached thereto or detached therefrom. The shield 240 in which the shielding portion 241 is held in the holding portion 242 is placed in the sputtering chamber 210.

As described above, in the sputtering apparatus 200 in this embodiment, a stacked film is formed on substrates having various sizes. In this embodiment, various types of shielding portions 241 each including a hole with a size corresponding to the size of various types of substrates are prepared in advance. In the sputtering apparatus-charging step (Step S102), a shielding portion 241 corresponding to the size of the substrate to be processed is used.

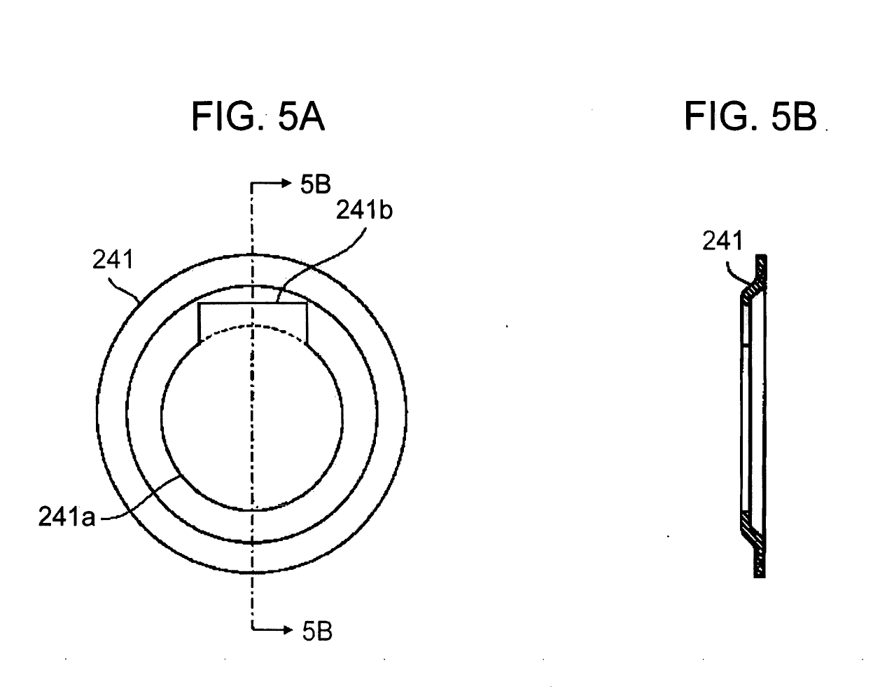

FIGS. 5A and 5B are views of the shielding portion 241 and correspond to FIGS. 4A and 4B, respectively.

FIG. 5A shows a front view of the shielding portion 241. FIG. 5B shows a cross-sectional view taken along line 5B-5B of FIG. 5A.

A circular hole 241a through which the magnetic material sputtered toward a predetermined circular area 221a including the surface of the substrate P passes is provided in the bottom of the shallow bowl-shaped portion of the shielding portion 241. Furthermore, a rectangular hole 241b is provided in the bottom portion of the shielding portion 241 so as to be integrated with the circular hole 241a. As shown in the hatched area of FIG. 4A, when the substrate holder 220 holding the substrate therein is vertically placed, the magnetic material sputtered toward an upper area 221b disposed in an upper portion of the substrate P in the substrate holder 220 passes through the hole 241b.

After the placement of the magnetic material target 230, the shield 240, and the substrate holder 220 holding the substrate therein in the sputtering chamber 210 is complete as described above, the sputtering film-forming step (Step S103) in which a magnetic film is formed on the surface of the substrate P is performed, as shown in the flowchart of FIG. 2. This sputtering film-forming step (Step S103) corresponds to an example of a first film-forming step in the present invention.

In the sputtering film-forming step (Step S103), first, in the sputtering chamber 210, evacuation is performed from the outlet 210a, and argon gas is then introduced from the gas inlet 210b. Thus, the sputtering chamber 210 is filled with argon gas. Next, the sputtering control unit 250 applies a high voltage to the magnetic material target 230. Consequently, electric discharge is generated from the magnetic material target 230 to the surrounding argon gas, and a part of the argon gas is ionized. Argon ions generated by ionization then collide with the magnetic material target 230, and thus the magnetic material is sputtered from the magnetic material target 230. The magnetic material sputtered from the magnetic material target 230 moves in a straight line as shown by the arrows D2 in FIG. 1 and moves toward the surface of the substrate P facing the surface of the magnetic material target 230.

In this case, in the sputtering chamber 210, an area other than the surface of the substrate P, the area 221a surrounding the substrate P, and the upper area 221b of the substrate holder 220, which are shown in FIG. 4A, are shielded from the magnetic material by the shield 240 disposed between the magnetic material target 230 and the substrate holder 220 holding the substrate therein. Accordingly, a magnetic film is formed on the surface of the substrate P, the area 221a surrounding the substrate P, and the upper area 221b of the substrate holder 220 by the magnetic substance passing through the integrated holes 241a and 241b provided in the shield 240 shown in FIG. 5A.

In this embodiment, the substrate holder 220 is used not only in the sputtering apparatus 200 but also in the CVD apparatus 300. After the magnetic film has been formed with the sputtering apparatus 200 as described above, a CVD apparatus-charging step (Step S104) is performed. In this CVD apparatus-charging step (Step S104), a substrate holder 220′ holding the substrate therein, in which the magnetic film has been formed on the substrate P and a part of the substrate holder 220, is placed in the CVD chamber 310 of the CVD apparatus 300 without further treatment.

In the CVD apparatus-charging step (Step S104), as in the arrangement in the sputtering chamber 210, the substrate holder 220′ is vertically placed in the CVD chamber 310. After the placement in the CVD chamber 310 is complete, a CVD film-forming step (Step S105) is performed. In the CVD film-forming step (Step S105), a carbon protective film is formed on the magnetic film formed with the sputtering apparatus 200.

In the CVD film-forming step (Step S105), first, evacuation is performed from an outlet 310a provided in the CVD chamber 310. Subsequently, in response to a command from the CVD control unit 350, the microwave source 330 supplies a waveguide 310b connected to the CVD chamber 310 with microwaves, the solenoid coil 340 applies a magnetic field, and the gas supply unit 320 supplies a compound gas containing carbon. As a result, electron cyclotron resonance is generated in the waveguide 310b by the synergistic effect between the microwaves and the magnetic field. This electron cyclotron resonance accelerates ionization of the compound gas supplied from the gas supply unit 320 to generate a high-density plasma.

In this step, evacuation is continued from the outlet 310a of the CVD chamber 310 so that the pressure in the CVD chamber 310 is maintained at a predetermined pressure. The high-density plasma flows in the CVD chamber 310 and fills the periphery of the substrate holder 220′ holding the substrate therein, the substrate holder 220′ being disposed in the CVD chamber 310. Carbon serving as an active species from the high-density plasma is deposited on the substrate P and the entire surface of the substrate holder 220′ to form a carbon protective film on the surface of the substrate P and the surface of the substrate holder 220′. The substrate holder 220′ is then taken out from the CVD apparatus 300, and the substrate P is separated from the substrate holder 220′. Thus, the process of forming a stacked film shown in the flowchart of FIG. 2 is finished, and a magnetic recording medium in which a stacked film including the magnetic film and the carbon protective film is formed on the surface of the substrate made of a nonmagnetic material can be obtained.

The CVD film-forming step (Step S105) corresponds to an example of a second film-forming step in the present invention.

In the process of this embodiment, a stacked film is formed on a plurality of substrates P. Accordingly, after the process including a series of steps of forming a stacked film on a single substrate P is performed, the process of forming a stacked film is performed using a new substrate P. In this process, the substrate holder 220 used in the previous process of forming the stacked film is used again without further treatment.

In this stage, the deposited carbon still remains on the substrate holder 220. The upper area 221b shown in FIG. 4A is a portion located at the upper part of a substrate P in the case where the substrate P to be processed is held in the substrate holder 220 and vertically placed inside the sputtering chamber 210 or the CVD chamber 310. Therefore, during the formation of a magnetic film with the sputtering apparatus 200 or during the formation of a carbon protective film with the CVD apparatus 300, if the carbon deposited on the upper area 221b is detached from the substrate holder 220, the carbon falls toward the substrate P on which a film is being formed, thereby interfering with formation of the film or damaging the resulting film. Consequently, a problem such as degradation of the quality of the magnetic recording medium may occur.

However, in this embodiment, the magnetic film is also formed on the upper area 221b of the substrate holder 220 in the sputtering apparatus 200 as described above. Since the carbon protective film formed with the CVD apparatus 300 is originally formed in order to protect the magnetic film formed on the substrate, the magnetic film has very good adhesion with carbon. Consequently, the carbon deposited on the upper area 221b in the CVD apparatus 300 is formed as a strongly adherent film, as in the carbon protective film formed on the substrate. Therefore, even when the substrate holder 220 on which deposited carbon still remains on the upper area 221b is vertically placed, detachment of carbon from the upper area 221b can be satisfactorily suppressed. Accordingly, the substrate holder 220 can be efficiently used for forming a stacked film on a new substrate P without performing cleaning or the like. Furthermore, when the substrate holder 220 is repeatedly used for a large number of substrates, a very strongly adherent stacked film in which magnetic films and carbon protective films are alternately stacked is formed on the upper area 221b, and thus detachment of the deposited object from this area can be satisfactorily suppressed. That is, in the stacked-film-forming system 10 of this embodiment, the substrate holder 220 can be efficiently used for a long period of time.

As described above, according to the stacked-film-forming system 10 of this embodiment, detachment of carbon deposited on the substrate holder 220 for holding a substrate can be satisfactorily suppressed. Consequently, the substrate holder 220 can be efficiently used for a long period of time without performing cleaning or the like.

An embodiment of a stacked-film-forming system of the present invention has been described using an example of the stacked-film-forming system 10 for forming a stacked film including a magnetic film and a carbon protective film. However, the present invention is not limited thereto. For example, the stacked-film-forming system of the present invention may be a system for forming a stacked film including different two types of films other than a magnetic film and a carbon protective film.

In addition, an embodiment of the stacked-film-forming system of the present invention has been described using an example of the stacked-film-forming system 10 for forming a two-layer stacked film including two types of films. However, the present invention is not limited thereto. For example, the stacked-film-forming system of the present invention may be a system for forming a stacked film in which two types of films are alternately stacked as three or more layers.

A holder used in the present invention has been described using an example of the substrate holder 220 that is vertically placed in both a sputtering apparatus and a CVD apparatus during the formation of a stacked film, i.e., the substrate holder 220 that is used in a state in which the substrate holder 220 is always vertically disposed during the formation of a stacked film. However, the present invention is not limited thereto. For example, a holder used in the present invention may be used in a state in which the holder is vertically placed only in a sputtering apparatus, or used in a state in which the holder is vertically placed only in a CVD apparatus.

According to an aspect of an embodiment of the present invention, a stacked-film-forming system for forming a stacked film includes a first film-forming apparatus including a holder having a frame surrounding the substrate and a holding mechanism for holding the substrate inside the frame so that a major surface of the substrate is vertically oriented, a material emission portion for emitting a material of a first film toward the substrate held in the holder, and a shield being disposed between the holder and the material emission portion and shielding areas except for a portion of the frame from the emitted material, the portion being located at the upper part of the substrate; and a second film-forming apparatus for forming, on the first film, a second film made of a material different from the material of the first film.

In the stacked-film-forming system of the embodiment, in the case where the holder is vertically placed and if a deposited object such as carbon is detached from the holder in the above-mentioned portion located at the upper part of the substrate, the detached object has a high probability of coming in contact with the substrate and damaging the substrate. However, in this stacked-film-forming system of the embodiment, this portion which may cause the above problem is eliminated from the area shielded by the shielding portion. Accordingly, the first film is formed on this portion with the first film-forming apparatus as on the surface of the substrate. This idea is contrary to the above-described known idea that good adhesion with a deposited object such as carbon is provided in advance on such a portion and the portion is protected as much as possible until a subsequent step in which such an object is inevitably deposited is performed. Here, a case where the first film is a magnetic film and the second film is a carbon protective film is considered. In this case, the carbon protective film is originally formed in order to protect the magnetic film formed on the substrate. Therefore, the magnetic film has excellent adhesion with carbon superior to that of the above-mentioned zinc plating film or the like. According to the stacked-film-forming system of the embodiment, a film having excellent adhesion with another film formed in the subsequent step, for example, a magnetic film and a carbon protective film, respectively, can be positively formed as the first film on such a portion which may particularly cause the above problem. As a result, when a second film is formed, a stacked film similar to the strongly adherent stacked film formed on the substrate can be formed on the portion. Therefore, detachment of a deposited object from this portion can be substantially prevented. Furthermore, for example, when the first film and the second film are stacked on a substrate as three or more layers and the holder is repeatedly used in the first film-forming apparatus and the second film-forming apparatus, or when only the first film and the second film are formed on a substrate, a plurality of such substrates including the two types of films are produced, and the holder is similarly repeatedly used, a strongly adherent stacked film in which films, whose adhesion with each other is satisfactory, are alternately stacked is formed on the portion which may otherwise particularly cause the above problem. Consequently, detachment of a deposited object from the portion can be satisfactorily suppressed. According to the stacked-film-forming system of the embodiment, detachment of an object deposited on a holder for folding a substrate can be satisfactorily suppressed.

In the stacked-film-forming system according to a preferred embodiment of the present invention, the holder may be repeatedly used for forming the stacked film a plurality of times.

According to the stacked-film-forming system of this preferred embodiment, the holder can be used in the first film-forming apparatus and the second film-forming apparatus when the stacked film is formed a plurality of times. Accordingly, the stacked film can be efficiently formed.

In the stacked-film-forming system according to an embodiment of the present invention, the holder may be used in a state in which the holder is vertically disposed during the formation of the first film using the first film-forming apparatus. Alternatively, the holder may be used in a state in which the holder is vertically disposed during the formation of the second film using the second film-forming apparatus. Alternatively, the holder may be used in a state in which the holder is vertically disposed during the formation of the stacked film.

From the standpoint of the system structure, it may be advantageous that the holder is used in a state in which the holder is vertically disposed because, for example, the space in the first film-forming apparatus or the second film-forming apparatus is limited. The risk of a deposited object falling from the holder is high when the holder is vertically disposed. However, according to the stacked-film-forming system of the present invention, even in such a case, detachment of the deposited object can be satisfactorily suppressed.

In the stacked-film-forming system according to an embodiment of the present invention, the second film-forming apparatus may be an apparatus for forming the second film on the surface of the first film by a CVD method.

As described above, in the CVD method, carbon or the like is inevitably deposited everywhere a compound gas containing the material of a film, such as carbon, reaches. Accordingly, during the formation of a film by the CVD method, it is difficult to prevent an object, such as carbon, from being deposited on the holder. However, according to the stacked-film-forming system of the present invention, during the formation of a film using the first film-forming apparatus, a film having very good adhesion with a deposited object can be formed on a portion where a problem of detachment of the object deposited during the formation of the film by the CVD method may particularly occur. As a result, even when an object is inevitably deposited on the portion by the CVD method, detachment of the deposited object can be satisfactorily suppressed.

According to another aspect of an embodiment of the present invention, a sputtering apparatus includes a holder having a frame surrounding a substrate and a holding mechanism for holding the substrate inside the frame so that the major surface of the substrate is vertically oriented; a material emission portion for emitting a material of a film toward the substrate held in the holder; and a shield being disposed between the holder and the material emission portion during the formation of the film and shielding areas except for a portion of the frame from the emitted material, the portion being located at the upper part of the substrate when the holder is vertically disposed.

According to this sputtering apparatus, even when an unnecessary object is inevitably deposited on the holder in a subsequent step performed after the film formation using this sputtering apparatus, detachment of the object deposited on the holder can be satisfactorily suppressed.

The sputtering apparatus of the embodiment can be used for any of the embodiments of the stacked-film-forming system described above. For example, the sputtering apparatus of the present invention can be used as the first film-forming apparatus.

According to another aspect of an embodiment of the invention, a method for forming a stacked film includes a holding step of holding the substrate in a holder having a frame surrounding a substrate and a holding mechanism for holding the substrate inside the frame so that the major surface of the substrate is vertically oriented; a first film-forming step of forming a first film on the substrate and the holder; and a second film-forming step of forming, on the first film, a second film made of a material different from a material of the first film in a state in which the substrate is held in the holder formed the first film thereon.

According to this method for forming a stacked film, detachment of an object deposited on the holder for holding a substrate can be satisfactorily suppressed.

Regarding the method for forming a stacked film, only a basic embodiment is described here. This is simply because overlap is prevented. The method for forming a stacked film of the present invention includes not only the above basic embodiment but also various other embodiments corresponding to the above-described embodiments of the stacked-film-forming system.

As described above, the embodiments can provide a stacked-film-forming system in which detachment of an object deposited on a holder for holding a substrate can be satisfactorily suppressed, a sputtering apparatus used in such a stacked-film-forming system, and a method for forming a stacked film that is performed by the stacked-film-forming system.

What is claimed is:

1. A stacked-film-forming system for forming a stacked film comprising:
a first film-forming apparatus including
a holder having a frame surrounding the substrate and a holding mechanism for holding the substrate inside the frame so that a major surface of the substrate is vertically oriented,
a material emission portion for emitting a material of a first film toward the substrate held in the holder, and
a shield being disposed between the holder and the material emission portion and shielding areas except for a portion of the frame from the emitted material, the portion being located at the upper part of the substrate; and
a second film-forming apparatus for forming on the first film a second film made of a material different from the material of the first film.

2. The stacked-film-forming system according to claim 1, wherein the second film-forming apparatus is an apparatus for forming the second film on the surface of the first film by a CVD method.

3. A sputtering apparatus comprising:
a holder having a frame surrounding a substrate and a holding mechanism for holding the substrate inside the frame so that the major surface of the substrate is vertically oriented;
a material emission portion for emitting a material of a film toward the substrate held in the holder; and
a shield being disposed between the holder and the material emission portion during the formation of the film and shielding areas except for a portion of the frame from the emitted material, the portion being located at the upper part of the substrate when the holder is vertically disposed.

4. A method for forming a stacked film comprising:
a holding step of holding the substrate in a holder having a frame surrounding a substrate and a holding mechanism for holding the substrate inside the frame so that the major surface of the substrate is vertically oriented;
a first film-forming step of forming a first film on the substrate and the holder; and
a second film-forming step of forming on the first film a second film made of a material different from a material of the first film in a state in which the substrate is held in the holder having the first film thereon.

5. The method according to claim 4, further comprising:
repeating the first and the second steps of forming another first and second films on the substrate and the holder.

6. The method according to claim 4, wherein the holder is vertically disposed in the first film-forming step.

7. The method according to claim 4, wherein the holder is vertically disposed in the second film-forming step.

8. The method according to claim 4, wherein the holder is vertically disposed in the first and the second film-forming steps.
